(19) United States
(12) Patent Application Publication
(10) Pub. No.: US 2002/0114949 A1
(43) Pub. Date: Aug. 22, 2002

(54) Process for controlled introduction of defects in elongated nanostructures

(76) Inventors: Christopher A. Bower, New Providence, NJ (US); Sungho Jin, Millington, NJ (US); Wei Zhu, Warren, NJ (US)

Correspondence Address: LOWENSTEIN SANDLER PC, 65 LIVINGSTON AVENUE, ROSELAND, NJ, 07068, US

(21) Appl. No.: 10/074,128

(22) Filed: Feb. 12, 2002

Related U.S. Application Data
(63) Continuation-in-part of application No. 09/512,873, filed on Feb. 25, 2000.

(51) Int. Cl. C23C 16/00

(52) U.S. Cl. 428/401; 427/569; 427/255.28; 428/364

(57) ABSTRACT

The invention provides a process capable of providing elongated nanostructures conformably aligned perpendicular to the local surface, while also allowing control over the diameter, length, and location. The process also permits controllably introducing defects at desired locations along the length. Conformably aligned straight sections are grown under the influence of an electrical field and curly defect regions are grown after switching off the field. A preferred embodiment uses high frequency plasma enhanced chemical vapor deposition (PECVD), typically with microwave-ignited plasma. The extraordinarily high extent of conformal alignment—on both flat and non-flat surfaces—appears to be due to the electrical self-bias imposed on the substrate by the plasma, the field line of which is perpendicular to the substrate surface. In addition to the conformal orientation, it was found that by selecting a particular thickness for the catalyst layer, it was possible to obtain nanotubes of a desired diameter, while the length of the nanostructure is determined by the duration of the PECVD process. And, by patterning the catalyst metal, it is possible to form nanostructures in particular locations on a substrate.

### CROSS REFERENCES TO RELATED APPLICATIONS

This is a continuation-in-part of U.S. patent application Ser. No. 09/512,873 filed by Christopher Bower et al. on Feb. 25, 2000 and entitled “Process For Controlled Growth of Carbon Nanotubes”, which is incorporated herein by reference.

### FIELD OF THE INVENTION

The invention relates to nanostructures and, in particular, to processes for attaining controlled growth and controlled introduction of defects in elongated nanostructures.

### BACKGROUND OF THE INVENTION

Elongated nanostructures such as nanotubes (hollow) and nanowires (solid) are important components in a variety of developing technologies. Elongated nanostructures typically have effective diameters of less than a few hundred nanometers and lengths of 0.5 to several hundred micrometers. Carbon nanotubes are the best known of these so-called “one-dimensional” (length) structures and find application in such diverse uses as hydrogen storage and electrical connection.

Carbon nanotubes are cylindrical shells of graphitic sheets typically having diameters of 1-50 nm and lengths of 1-10 μm. They offer unique physical properties that are potentially useful in a variety of nanometer-scale devices and technologies. See, e.g., C. Dekker, “Carbon nanotubes as molecular quantum wires,” Physics Today, May 1999. Most of those envisioned applications, however, require that the nanotubes be grown in a highly controlled fashion, i.e., with their orientation, as well as their diameter, length, location and microstructure, controllable and reproducible. There have been reports of growth of aligned nanotubes using porous templates (W. Z. Li et al., “Large Scale Synthesis of Aligned Carbon Nanotubes,” Science, Vol. 274, 1701 (1996); S. Fan et al., “Self-oriented regular arrays of carbon nanotubes and their field emission properties,” Science, Vol. 283, 512 (1999); J. Li et al., “Highly ordered carbon nanotubes arrays for electronic applications,” Appl. Phys. Lett., Vol. 75, 367 (1999)). Other papers on growing aligned nanotubes have described dc plasma assisted hot filament deposition (Z. F. Ren et al., “Synthesis of large arrays of well-aligned carbon nanotubes on glass,” Science, Vol. 282, page 1105 (1998)). But a process providing substantial control of both the geometric and structural properties of the tubes has not been available.

In addition, it has been observed that carbon nanotubes exhibit unique electrical properties. Depending on their diameters and chirality, carbon nanotubes, in particular single wall carbon nanotubes, can be either one-dimensional metals or semiconductors. Single-electron transistors employing metallic nanotubes and field effect transistors employing semiconductor nanotubes have been demonstrated. Intramolecular junction devices have also been proposed which should display a range of other device functions. It is desired to exploit these electrical properties to make molecular level electronic devices, but nanotube growth processes have not been adequate to achieve this result. There are currently no practical means to grow carefully designed molecular junction structures of carbon nanotubes for potential active molecular-level device applications. Presently such molecular-level junctions are identified in nanotubes with a mechanical bent or a kink-type defect that is neither controllable nor reproducible.

Thus, there is a need for improved processes for attaining controlled growth and controlled introduction of defects in elongated nanostructures.

### SUMMARY OF THE INVENTION

The invention provides a process capable of providing elongated nanostructures conformably aligned perpendicular to the local surface, while also allowing control over the diameter, length, and location. The process also permits controllably introducing defects at desired locations along the length. Conformably aligned straight sections are grown under the influence of an electrical field and curly defect regions are grown after switching off the field. A preferred embodiment uses high frequency plasma enhanced chemical vapor deposition (PECVD), typically with microwave-ignited plasma. The extraordinarily high extent of conformal alignment—on both flat and non-flat surfaces—appears to be due to the electrical self-bias imposed on the substrate by the plasma, the field line of which is perpendicular to the substrate surface. In addition to the conformal orientation, it was found that by selecting a particular thickness for the catalyst layer, it was possible to obtain nanotubes of a desired diameter, while the length of the nanostructure is determined by the duration of the PECVD process. And, by patterning the catalyst metal, it is possible to form nanostructures in particular locations on a substrate.

Structural defects in long nanostructures can be controllably introduced along the length by turning off the plasma for brief periods during the growth and then turning the plasma back on. By turning on or off the plasma source, which essentially switches on or off the alignment (i.e., linear growth) mechanism, either straight or “curly” regions in a repeated manner can be grown. A desired junction-type defect is thus introduced at the physical junction of a straight and “curled” nanotube at any selected location along the length.

The introduction of these junction-type defects induces changes in atomic structures of the resumed growth, which in turn changes electrical properties such as the electrical resistivity and the band gap. As a result, the defects function as important device nodes such as intramolecular metal-metal, metal-semiconductor (Schottky diode), or semiconductor-semiconductor (p-n) junctions.

### BRIEF DESCRIPTION OF THE DRAWINGS

FIG. 1 illustrates an apparatus suitable for performing a microwave plasma enhanced chemical vapor deposition process.

FIGS. 2A-2E illustrate a nucleation and growth model for nanostructures in the PECVD process.

FIG. 3 is a scanning electron microscope micrograph showing conformably aligned nanotubes on a flat surface formed according to the invention.

FIGS. 4A and 4B shows scanning electron microscope micrographs of conformably aligned nanotubes on non-flat surfaces formed according to the invention.

FIG. 5 shows the relationship of catalyst layer thickness to diameter of the grown nanotubes.

FIG. 6 shows the relationship of nanotube length to the duration of the PECVD process.

FIG. 7 shows an apparatus suitable for increasing the speed of nanotube fabrication according to the invention.

FIG. 8 is a schematic view of a nanotube grown with an intermediate defect region.

FIG. 9 is a schematic view of nanotube grown with an end defect region.

FIGS. 10A and 10B illustrate device node structures of nanotubes grown with controlled defects.

FIGS. 11A, 11B and 11C depict nanotubes grown with defect regions.

### DETAILED DESCRIPTION OF THE INVENTION

According to the invention, elongated nanostructures are grown conformably aligned to the local surface of a substrate. Conformably-aligned to the local surface means that the nanostructures are perpendicular to the substrate surface at the point of attachment to the surface, regardless of the surface curvature or contour, with an average deviation from perpendicular of less than 15°, as measured by x-ray diffraction. It is also possible to select the process parameters to provide a particular diameter, length, and/or location.

As a specific example, multi-wall carbon nanotubes are formed by high frequency plasma enhanced chemical vapor deposition (PECVD), where the high frequency is generally provided by RF or microwave sources. (As used herein, high frequency indicates 50 kHz or greater. RF or radio frequency indicates 50 kHz to 300 MHz, and microwave frequency indicates 300 MHz to 300 GHz.) A microwave PECVD technique is generally known as a technique for depositing diamond thin films, as discussed, for example, in P. K. Bachmann and R. Messier, “Emerging technology of diamond thin films,” Chemical and Engineering News, May 15, 1989. As shown in FIG. 1, an MPECVD system contains a vacuum chamber 10 equipped with a microwave source 11 and a heater 12. The substrate 13 is placed on the heater 12, and a gas 15, e.g., an ammonia and acetylene mixture, is directed into the chamber 10. A plasma 14 is ignited above the substrate from the gas 15 by, in this embodiment, microwave energy. Typical microwave energy frequencies are 2.45 GHz and 915 MHz. (A typical RF frequency is 13.56 MHz.) The substrate temperature is generally kept between 500 and 1000° C. The typical plasma parameters include a microwave power input of 1-5 kW and a gas pressure of 10-100 Torr.

The high level of conformal alignment, reflected in the Examples below, is provided by the unique characteristics of the high frequency PECVD process employed. The high frequency PECVD is performed with a gaseous carbon-based chemistry, advantageously an acetylene-ammonia chemistry. The acetylene (C₂H₂) provides the carbon species necessary for nanotube formation, although it is also possible to use other carbon-containing gases, such as methane and carbon dioxide, as the carbon source. The ammonia appears to promote or modify chemical reactions in the gas phase (such as decomposition of acetylene) as well as on the substrate surface (such as reactions involving carbon and catalyst metal as well as etching of nanotubes), although the exact nature of its role is not clear. The conformal alignment is believed to occur due to the high frequency PECVD process's creation of an electrical self-bias potential on the substrate surface. The field line of the potential is perpendicular to the surface of the substrate, and the nanotubes tend to grow along these field lines. It is believed that the relatively heavy molecular mass of the ions in the ammonia-acetylene plasma chemistry, particularly the ammonia, help to sustain a sufficiently strong electrical field near the surface. Specifically, because the self-bias potential is proportional to the mass of the ions (see B. Chapman, Glow Discharge Processes, John Wiley and Sons, 1980, page 70), the use of the relatively heavy ammonia-based plasma appears to be helpful in establishing a sufficiently strong local field at the surface, compared with other types of lighter-mass plasmas such as hydrogen-based plasma. This high level of tube alignment appears to be obtainable only from the high frequency plasma environment. Thermal processes alone under otherwise identical conditions have yielded completely randomly oriented nanotubes. Moreover, the type of conformal alignment achieved by the invention was reportedly not achieved by processes in which a high frequency plasma is not employed, e.g., —a DC plasma assisted hot filament deposition process as practiced by Ren et al., “Large arrays of well-aligned carbon nanotubes”, Proceedings of 13^{th} International Winter School on Electronic Properties of Novel Materials, 263, (1999). According to the Ren et al. process, the nanotubes do not grow conformably aligned perpendicular to the local substrate surface, but instead grow at some other angles to the surface.

In an advantageous embodiment, a microwave PECVD process is carried out under a pressure of 1333 to 13330 N/m² (10-100 Torr), with the substrate temperature at 500 to 1000° C. Total flow rates of acetylene and ammonia typically range from 30 to 30000 sccm (standard cubic centimeter per minute), and the mass flow ratio of acetylene to ammonia is typically 10 to 50%. The deposition procedure is typically performed as follows. The ammonia gas is introduced first to reach the desired pressure. The heater is then turned on to reach the desired substrate temperature, at a typical temperature ramp rate of about 40°/minute. Once the temperature is reached, the plasma is initiated, the acetylene gas is fed into the chamber, and the growth starts. Growth is typically performed from 30 seconds to 30 minutes, depending on the particular length desired. During the process shutdown, the flow of acetylene gas is stopped first, and then the plasma and heater are turned off. Once the temperature reaches room temperature, the ammonia gas is turned off, the chamber is back-filled with argon to atmospheric pressure, and the substrate is removed.

Suitable substrate materials include a variety of materials, including metals, semiconductors and insulators such as Si, SiO₂, Hf, AlN, Al₂O₃, Si₃N₄, and diamond. It is possible that the substrate will, in practice, be a portion of a device, e.g., a silicon-based integrated circuit device, on which nanotube formation is desired. In addition, where silicon is used, the silicon advantageously has a thin, e.g., about 2 nm, native oxide present to impede excessive reactions between Si and the catalyst metal.

A catalyst metal is provided on the substrate, prior to the nanotube growth, to help initiate nanotube formation. (Catalyst metal includes suitable metals as well as compounds, e.g., oxides or organometallics, containing the metal.) The catalyst is generally selected from Fe, Co, Ni, or alloys thereof and is typically formed on a substrate in a thin layer. (As used herein, “layer” encompasses both continuous and patterned, i.e. discontinuous, layers.) It is possible to form the catalyst layer by any suitable thin film technique such as sputtering, evaporation, or electrodeposition. Cobalt, for example, is typically sputtered onto the substrate. The thickness of the catalyst metal films, typically 0.5 to 200 nm, substantially controls the diameter of the nanotubes. For these typical thicknesses, at least a portion of the deposited film may form an oxide of the catalyst metal. To attain a patterned layer of the catalyst, as might be useful in some device structures, it is possible to use lithographic techniques or a shadow mask during the metal deposition. For example, it is contemplated to place the catalyst metal into trenches or vias of device structures in order to grow nanotubes as device interconnections.

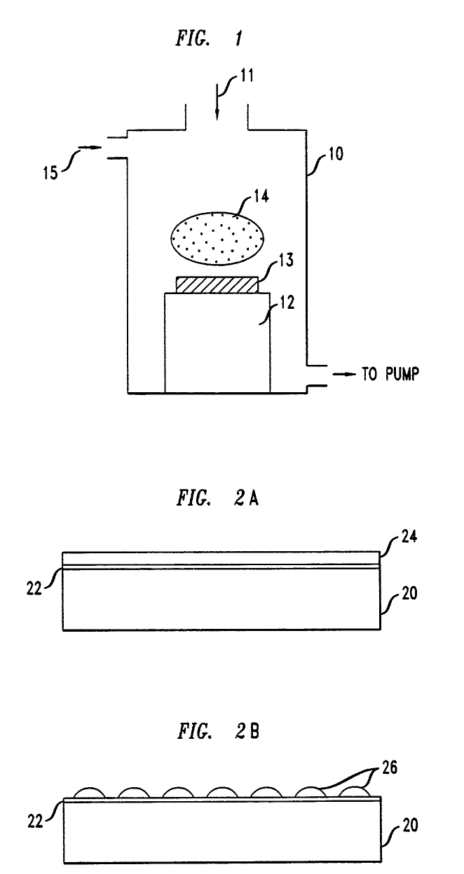

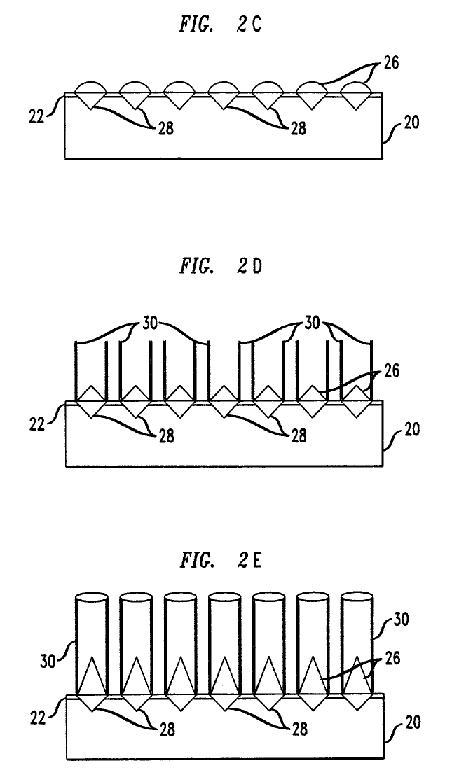

It is believed that nanotube growth in the process of the invention occurs according to the following model, reflected in FIGS. 2A-2E, although the invention is not limited to any aspect of this proposed model. First, as shown in FIG. 2A, a catalyst metal 24 (or oxide or other compound of a suitable metal) is deposited on a native-oxide 22 covered silicon substrate 20 which, for illustrative purposes, has a flat surface. The presence of this thin native oxide 22 (˜2 nm) on the silicon 20 is believed to be significant, in that the oxide desirably impedes reactions of the catalyst and silicon. This ensures that the silicide formation does not consume all the free metal catalyst on the surface.

Next, as shown in FIG. 2B, during a temperature ramp up in ammonia or hydrogen gas (up to about 10 minutes), the catalyst on the surface starts to form semi-spherical shaped islands 26, driven by thermodynamics or by surface tension to lower the total energies during heating (as confirmed by the observation of morphology evolution via scanning electron microscopy). The formation of these three-dimensional islands 26 is significant to the nucleation and growth of nanotubes and appears to be promoted by the presence of the native oxide layer 22.

As reflected in FIG. 2C, during the later stage of the temperature ramp up and the initiation of the plasma, both the surface catalyst and the native SiO₂ are reduced, and catalyst-silicides 28 are formed at the interface. These silicides 28 appear to serve as anchors or adhesion promoters for the catalyst islands 26 formed at the surface.

As shown in FIG. 2D, during the initial stages of the NH₃-C₂H₂ high frequency PECVD, nanotubes 30 nucleate and grow from the catalyst islands 26 with field-induced orientational alignment, as discussed above. (Growth of nanotubes “from” or “on” the catalyst metal means that nanotube formation is initiated on the catalyst metal.) It is believed that the nucleation and growth occurs through carbon reactions with the catalyst, i.e., dissolution, saturation and precipitation, such that the nanotubes grow by extrusion from the base region. The catalyst islands 26 gradually transform into a conical shape and become confined to the ends of the nanotubes 30 proximate the substrate 20.

As shown in FIG. 2E, the growth of nanotubes 30 is believed to continue, both in diameter and length, until the conical shaped catalyst particles 26 are completely encased by the nanotube shells on the substrate side. When this encasement occurs, the growth slows significantly and the etching nature of the high frequency PECVD process begins to dominate if the sample remains exposed to the plasma. It is also possible for smaller fragments of catalyst particles to be trapped at various locations along the tubes.

The nanotube growth, according to the invention, and consistent with this model, is controllable at least as to orientational alignment, diameter, length, location of the nanotubes, and location of defects along the nanotubes.

The orientational alignment, as discussed, is provided by the electrical self-bias potential created by the high frequency PECVD process, particularly with the acetylene-ammonia chemistry, or similar chemistries involving relatively large ions.

The diameter of nanotubes is controllable by selecting a particular catalyst layer thickness. For example, by varying the thickness of a cobalt layer from 2 nm to 60 nm, the nanotube diameter goes from about 30 nm to about 150 nm. Consistent with the model, the size of the catalyst islands is determined, as least in part, by the thickness of the catalyst layer, with thin layers leading to smaller diameter islands, and thicker layers leading to larger diameter islands. The range of nanotube diameters typically attainable is 10 to 300 nm. Control runs are easily performed to determine an appropriate catalyst layer thickness for a desired nanotube diameter.

The nanotube length is primarily controlled by the duration of the high frequency PECVD process, but not in a monotonically linear fashion. As noted in Example 5 below, there are three stages of the process as it affects length—growth, stability, and etch. Specifically, length initially increases for a certain time period (about 5 minutes from the initiation of the process for the experiments detailed below). This growth stage is followed by a period of substantially slowed growth—the stability stage. And then the nanotubes begin to be etched away such that the length is reduced—the etch stage. It appears, consistent with the model, that at some point during nanotube growth catalyst particles become completely encased by graphitic shells. Once the catalyst is so encased, nanotube growth slows (stability stage), and the etching character of the high frequency PECVD process begins to predominate (etch stage). It is also possible that the increasing length of the nanotubes interferes with the ability of reactive species to reach the catalyst at the bottom of the growing tube, thereby slowing the growth. Thus, for a given set of high frequency PECVD process parameters, the duration will typically be chosen to attain a desired length, without entering into the etch stage. However, it is possible to reach any of the three stages, and it is possible for certain advantages to exist in each. For example, it is possible that moving at least partially into the etch stage will provide nanotubes with open, as opposed to capped, ends, which may be desirable for some applications. Typical lengths attainable with the process of the invention range from 0.5 to 30 μm. Control runs are easily performed to find a suitable process duration to provide a desired length.

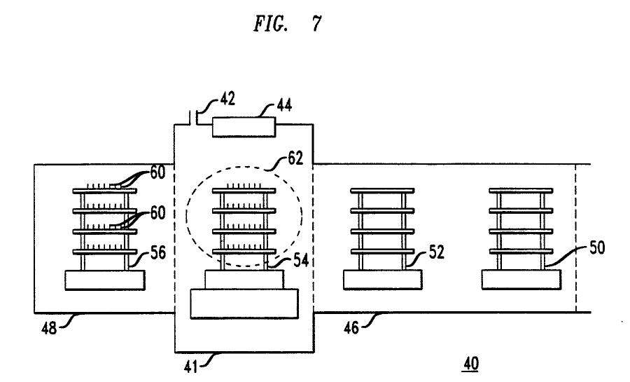

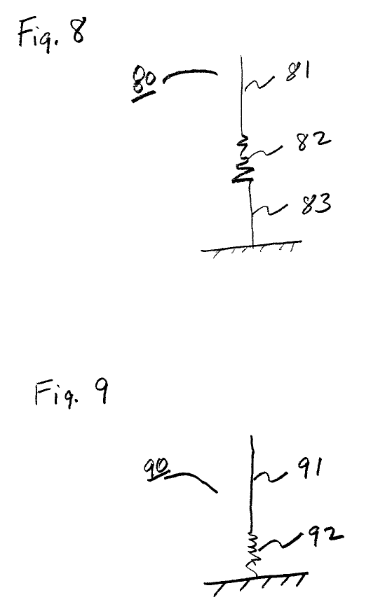

The high growth rate of the process, e.g., as high as 5 82 m per minute (in terms of nanotube height), is about 30 times higher than plasma-free thermal CVD processes with identical deposition conditions. To take further advantage of this high rate, it is possible to use a continuous or semi-continuous PECVD process, optionally with multiple substrates on which nanotubes are formed simultaneously. For example, FIG. 7 shows one such apparatus 40. The apparatus 40 contains a reaction chamber 41 (both closed-reactor and open-reactor types of PECVD are possible), gas supply and control systems (e.g., gas inlet 42), a plasma generating circuit 44, multiple-substrate support stands 50, 52, 54, 56, continuous or semi-continuous feed systems (e.g., load chamber 46 and unloading chamber 48), as well as other components apparent to one skilled in the art. The high-speed fabrication of the nanotubes 60 is able to be performed on single- or double-sided substrates, in a plasma 62 large enough to cover all the substrates. Advantageously, the plasma exhibits an average diameter of at least 20 cm, more advantageously at least 40 cm. The resultant growth rate according to this increased-speed apparatus, per 1 μm height of nanotubes, is advantageously at least 0.01×10⁶ cm² per hour, more advantageously at least 0.5×10⁶ cm² per hour.

We have attributed the alignment of the nanotubes to the electrical self-bias imposed on the substrate surface from the plasma environment. We further discovered that by switching on or off the plasma source, defective structure can be deliberately introduced at the physical junction between the plasma-grown nanotube (typically straight) and a thermally grown “curly” nanotube. This switching provides the capability of controllably introducing defective regions along the length of a growing nanotube. Such defects permit the growth of nanotubes having changed atomic structure along their lengths, which, in turn, will change their electronic properties.

Similar growth under an electric field which is switched on and off is expected to controllably grow straight and curly defect regions, respectively, in other one-dimensional nanostructures such as silicon or germanium nanowires.

FIG. 8 is a schematic illustration of a nanotube 80 grown, as described above, with an initial straight region 81, a curly defect region 82, and a second straight region 83. The regions 81, 83, having different initial conditions for straight growth, can have different atomic structures (for example, different chirality) producing significantly different electrical properties.

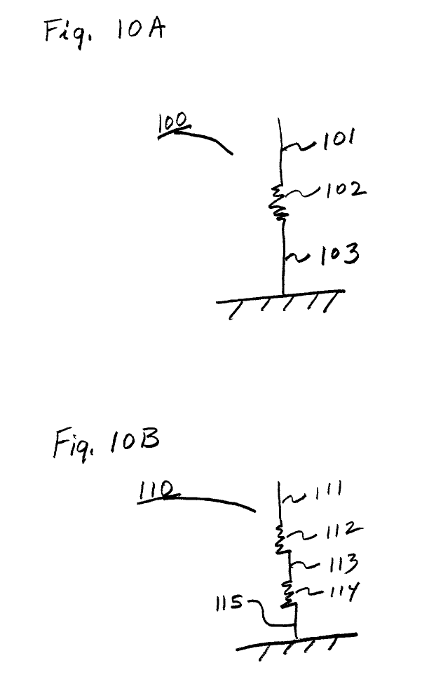

FIG. 9 is a schematic drawing of a nanotube grown to produce a single curly defect region. The nanotube go comprises a straight region 91 grown with the plasma on and a curly defect region 92 thermally grown with the plasma off.

Defects can change the electrical properties of the nanotube, such as its electrical resistivity and bandgap. M. S. Dresselhaus et al., Science of Fullerene and Carbon Nanotubes, Academic Press (San Diego, 1996), and Yao et al., Nature, vol. 402, page 273, 1999. Consequently the ability to deliberately introduce defect-related junctions along the length of a nanotube permits the growth of molecular level device structure. It is believed that a defect-related junction is formed at the junction of a straight and curly region. For these purposes a straight region is one with no abrupt deviation along its length of more than two degrees within a half micrometer of length and preferably with no deviation of more than one degree within a micrometer of length. A curly region is one having a deviation of more than two degrees within a micrometer and preferably more than 10 degrees. A curly region will also be referred to as a defect region in the nanotube or nanowire.

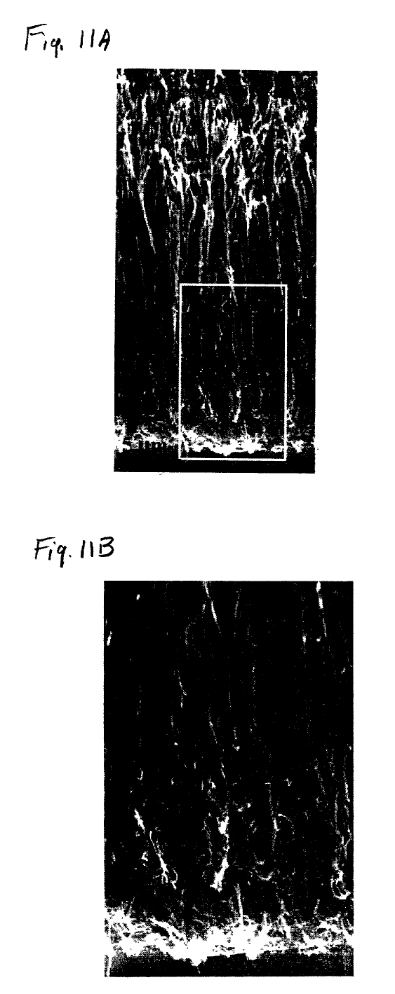

FIGS. 10A and 10B illustrate contemplated nanoscale device node structures. FIG. 10A schematically illustrates a molecular rectifying node comprising an elongated nanostructure 100 comprising straight sections 101, 103 separated by a curly defect region 102. Region 101 can be grown as semiconductive (either n or p) and defect region 102 disrupts the atomic structure for further growth so that region 103 is either of the opposite conductivity type (p or n) or is metallic. In the former case a nanotube acts as a pn junction rectifier. In the latter, a nanotube acts as a Schottky diode. For these devices the defect region is advantageously short, as would be grown by switching the plasma off for 1-60 seconds.

FIG. 10B schematically illustrates a transistor-like device comprising an elongated nanostructure 110 having a pair of defect regions 112, 114 separating straight regions 111, 113, 115. Here the defect regions 112, 114 provide device nodes, such as metal-semiconductor intra-molecular junctions, that can be used in the fabrication of molecular level active devices.

While the preferred application of the process for controllably introducing defects is in conjunction with the growth of straight, aligned nanostructures, it will be recognized that the controlled introduction of defects is useful even if the nanostructures are not straight or aligned, so long as they retain the same atomic structure until encountering defect regions.

The invention will be further clarified by the following examples, which are intended to be exemplary. The microwave PECVD system used in the examples consisted of a 2.45-GHz 5 kW microwave power supply with a rectangular waveguide coupled to a cylindrical growth cavity, a 6-inch inner-diameter stainless-steel chamber, and a molybdenum substrate stage with a RF heater that allowed independent control of the substrate temperature from the plasma power. During processing, the substrate temperature was maintained at 825° C., and the chamber pressure was kept at 20 torr (or 2666 N/m²). Total gas flow rates of acetylene (C₂H₂) and ammonia (NH₃) were controlled at 200 sccm, and the mass flow ratio of C₂H₂ over NH₃ was varied in the range of 10-30%.

The nanotubes were grown by microwave PECVD on cobalt-coated silicon substrates or silica fibers. The cobalt was applied by DC magnetron sputtering at a power density of 9 W/cm², and was apparently oxidized due to the very thin nature of the coating. The microwave PECVD typically lasted from 30 seconds to 30 minutes.

### EXAMPLE 1

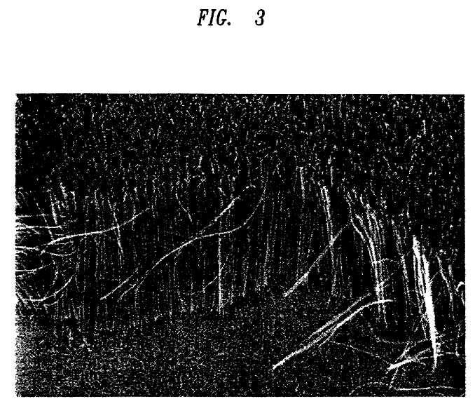

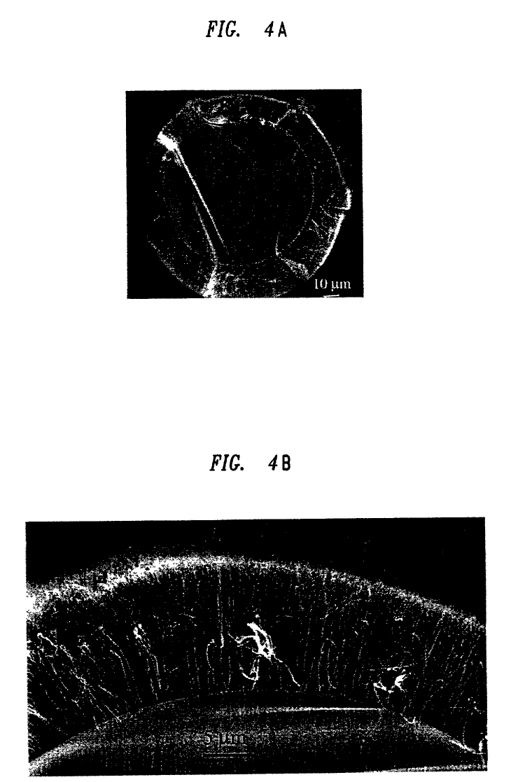

A 2 nm thick cobalt layer was deposited onto a silicon substrate. The microwave PECVD process was performed for 2 minutes at a C₂H₂/NH₃ mass flow ratio of 20%. FIG. 3 shows a scanning electron microscope micrograph of the resultant nanotubes, which were multiwalled nanotubes having diameters of about 30 nm and lengths of about 10 μm. X-ray diffraction measurements indicated an average deviation of the tubes from the normal to the surface of less than 10°. For a cold microwave plasma (cold indicating that the temperature of ions and neutrals is much lower—near room temperature—than the electron temperature which can be tens of thousands of degrees) of ammonia and acetylene mixture at 1 kW microwave input power and 20 torr (2666 N/m²) pressure, the self-bias potential created by the PECVD process is estimated to be 10 V across a sheath of 100 μm. This would generate a field of 0.1 V/μm in the vicinity of the surface, which is sufficient to align the nanotubes.

### EXAMPLE 2

To confirm the affect of the self-bias potential, and the conformal perpendicular alignment on flat surface, a process identical to Example 1 was performed in which flat silicon substrates were placed in either a vertical or tilted position, in addition to the normal horizontal position, on the substrate stage. The nanotubes grew perpendicular to the substrate surface regardless of the substrate position.

### EXAMPLE 3

To confirm the ability to form conformably aligned nanotubes perpendicular to the local surface of non-flat substrates, the process of claim 1 was performed on a telecommunications-grade, 125 μm diameter silica optical fiber. FIGS. 4A and 4B show the resultant structure, in which the nanotubes point radially outward perpendicular to the local surface. This result shows the dominating role of the local DC electrical self-bias field in attaining the conformal alignment of the nanotubes.

### EXAMPLE 4

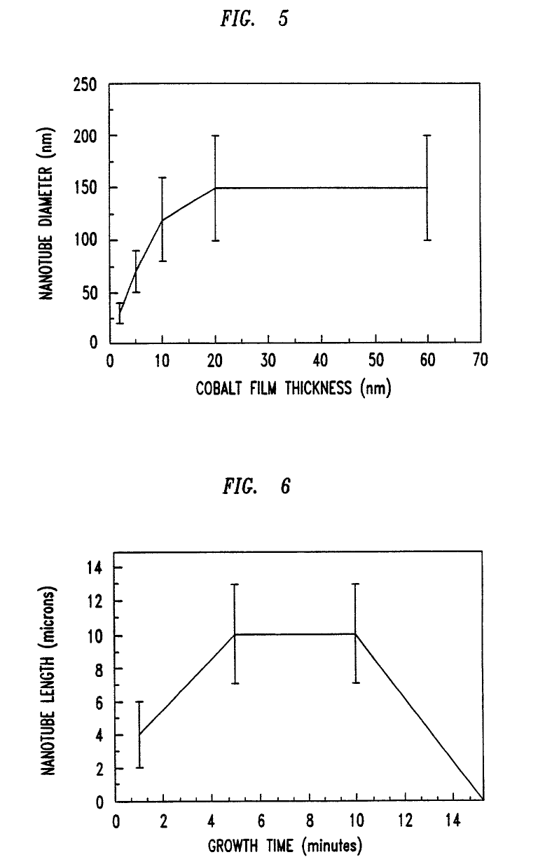

The deposition procedure of Example 1 was followed for cobalt layers having thicknesses (in addition to the 2 nm layer of Example 1) of 5, 10, 20, and 60 nm to examine the effect of the thickness on nanotube diameter. As shown in FIG. 5, the average diameter of nanotubes increased as the cobalt thickness increased. Above a cobalt thickness of 20 nm, the nanotube diameter appeared to become saturated at about 150 nm under the particular growth conditions.

### EXAMPLE 5

Following the procedure of Example 1, again with a cobalt layer thickness of 2 nm, nanotube length was monitored for varying process times. As shown in FIG. 6, there were three stages—growth, stability, and etch. The average growth rate in terms of tube length for the first 5 minutes was about 1 μm/minute. Above 5 minutes, growth slowed, and at around 10 minutes, nanotube length decreased. (These results are specific to the particular growth conditions.)

### EXAMPLE 6

Nanotubes were initially grown straight with the plasma on as described herein and then grown with the plasma off. Specifically, they were grown with the plasma on during the first two minutes to grow straight sections. Then they were grown with the plasma off for 70 minutes to grow curly defect regions. The growth rate with the plasma off is about 1/30 the rate with the plasma on.

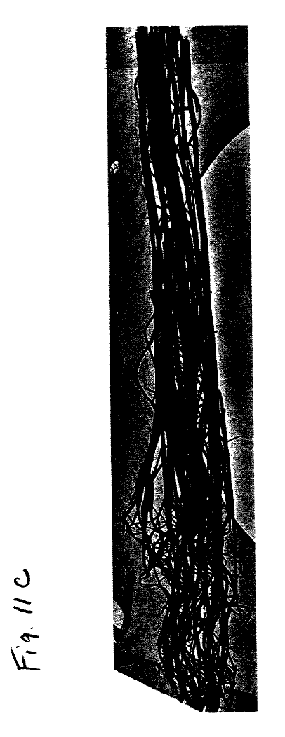

FIGS. 11A and 11B are SEM micrographs of the nanotubes grown to have a single defect region (curly portion) in each. FIG. 11B is an enlarged view of the rectangular box in 11B.

FIG. 11C is a TEM micrograph of nanotubes shown in FIG. 11 A showing the transition from curly to straight nanotubes, which can serve as molecular junctions. Thus the inventive method permits the growth of straight or defective regions in a controlled manner.

Other embodiments of the invention will be apparent to those skilled in the art from consideration of the specification and practice of the invention disclosed herein.

What is claimed is:

1. The process of fabricating an article comprising the steps of:
providing a substrate having a surface including one or more regions of catalyst metal for catalyzing the growth of elongated nanostructures;
growing on said one or more regions at least one elongated nanostructure having at least one substantially straight region and at least one curly defect region, the straight region grown under the influence of an electrical field and the curly defect region grown with the field off.

2. The process of claim 1 wherein:
the straight region is grown by chemical vapor deposition enhanced by plasma induced by a high frequency plasma source, and
the curly defect region is grown thermally while the plasma source is off.

3. The process of claim 2 wherein the defect region is grown by shutting off the plasma source for 1-60 seconds.

4. The process of claim 2 wherein the elongated nanostructure is a nanotube.

5. The process of claim 4 wherein the nanotube comprises in sequence a first substantially straight region, a defect region and a second substantially straight region.

6. The process of claim 4 wherein the nanotube comprises in sequence a first substantially straight region, a defect region, a second substantially straight region, a second defect region, and a third substantially straight region

7. The process of claim 4 wherein the nanotube exhibits electrically rectifying properties.

8. The process of claim 2, wherein the frequency is 915 MHz, 2.45 GHz, or 13.56 MHz.

9. The process of claim 4 wherein the plasma enhanced chemical vapor deposition is performed with a chemistry comprising ammonia.

10. The process of claim 4 wherein the plasma enhanced chemical vapor deposition is performed with a chemistry comprising ammonia and acetylene.

11. The process of claim 10, wherein the mass flow ratio of acetylene to ammonia is 10 to 50%.

12. The process of claim 4, wherein the substrate comprises a material selected from the group consisting of silicon, silica, Hf, AlN, Al₂O₃, Si₃N₄ and diamond, and the catalyst metal layer comprises an element selected from the group consisting of cobalt, nickel, iron, and alloys thereof.

13. The process of claim 12, wherein the catalyst metal layer is present in a thickness of 0.5 to 200 nm.

14. The process of claim 12, wherein the substrate comprises silicon or silicon oxide and the catalyst metal layer comprises cobalt or iron.

15. The process of claim 13, wherein the average nanotube diameter is 10 to 300 nm.

16. The process of claim 2, wherein the elongated nanostructures have an average length of 0.5 to 30 micrometers.

17. The process of claim 4, wherein at least a portion of the nanotubes comprise one or more encased catalyst metal particles.

18. The process of claim 17, wherein the encased catalyst metal particles are located proximate the substrate surface.

19. The process of claim 2, wherein the catalyst metal layer is a patterned layer, such that the nanostructures form in the pattern.

20. The process of claim 17, wherein the catalyst metal thickness controls the nanotube diameter.

21. The process of claim 4, wherein the high frequency plasma enhanced chemical vapor deposition process exhibits stages of growth, stability, and etch as to nanotube length.

22. The process of claim 2, wherein the plasma enhanced chemical vapor deposition induces formation of distinct islands of the catalyst metal, the nanostructure growth initiating on such islands.

23. The process of claim 2, wherein the growth rate of the nanostructures in height is at least 5 micrometers per minute.

24. The process of claim 23, wherein the growth rate per micrometer height is at least 0.01×10⁶ cm² per hour.

25. An article comprising an elongated nanostructure having in sequence a straight region and a curly defect region, the nanostructure acting as an electrical rectifier.

26. An article comprising an elongated nanostructure having in sequence a straight region, a curly defect region and a straight region, the nanostructure acting as an electrical rectifier.

27. An article comprising an elongated nanostructure having in sequence a straight region, a curly defect region, a second straight region, a second curly defect region and a third straight region, the nanostructure acting as an electrical rectifier.
